(19) United States
(12) Patent Application Publication
(10) Pub. No.: US 2013/0269613 A1
(43) Pub. Date: Oct. 17, 2013

(54) METHODS AND APPARATUS FOR GENERATING AND DELIVERING A PROCESS GAS FOR PROCESSING A SUBSTRATE

(71) Applicant: APPLIED MATERIALS, INC., Santa Clara, CA (US)

(72) Inventors: ERROL ANTONIO C. SANCHEZ, Tracy, CA (US); DAVID K. CARLSON, San Jose, CA (US)

(21) Appl. No.: 13/803,181

(22) Filed: Mar. 14, 2013

Related U.S. Application Data
(60) Provisional application No. 61/617,877, filed on Mar. 30, 2012.

(51) Int. Cl. H01L 21/02

(52) U.S. Cl. CPC H01L 21/02104
USPC 118/724; 118/715

(57) ABSTRACT

Methods and apparatus for generating and delivering process gases for processing substrates are provided herein. In some embodiments, an apparatus for processing a substrate may include a container comprising a lid, a bottom, and a sidewall, wherein the lid, the bottom, and the sidewall define an open area; a solid precursor collection tray disposed within the open area; a gas delivery tube disposed within the open area and extending toward the solid precursor collection tray to provide a gas proximate the solid precursor collection tray; and a purge flow conduit coupled to the open area.

### CROSS-REFERENCE TO RELATED APPLICATIONS

This application claims benefit of U.S. provisional patent application Ser. No. 61/617,877, filed Mar. 30, 2012, which is herein incorporated by reference in its entirety.

### FIELD

Embodiments of the present invention generally relate to semiconductor processing equipment.

### BACKGROUND

The inventors have observed that conventional Group III-V deposition processes typically use hydride sources and organo-metallic sources that are difficult to handle safely due to the high flammability and/or high toxicity of these sources. In addition, the use of certain organo-metallic sources for such processes requires complex and expensive delivery systems. The inventors have further observed that conventional systems used to form gaseous precursors from solid state materials typically utilize pre-filled sealed ampoules to contain the solid state materials during the evaporation/sublimation process. However, when the solid state material contained within the pre-filled ampoules become exhausted the pre-filled ampoule must be removed from the process chamber and replaced, thus leading to process downtime. Moreover, the inventors have discovered that when using pre-filled ampoules the solid state material may pack unevenly during transportation or installation, thus leading to non-uniform gas movement or gas channeling through the solid state material, thereby causing a non-uniform formation and/or dispersion of gaseous precursor.

Therefore, the inventors have provided improved methods and apparatus for generating and delivering process gases for processing substrates.

### SUMMARY

Methods and apparatus for generating and delivering process gases for processing substrates are provided herein. In some embodiments, an apparatus for processing a substrate may include: a container comprising a lid, a bottom, and a sidewall, wherein the lid, the bottom, and the sidewall define an open area; a solid precursor collection tray disposed within the open area; a gas delivery tube disposed within the open area and extending toward the solid precursor collection tray to provide a gas proximate the solid precursor collection tray; and a purge flow conduit coupled to the open area.

Other and further embodiments of the present invention are described below.

### BRIEF DESCRIPTION OF THE DRAWINGS

Embodiments of the present invention, briefly summarized above and discussed in greater detail below, can be understood by reference to the illustrative embodiments of the invention depicted in the appended drawings. It is to be noted, however, that the appended drawings illustrate only typical embodiments of this invention and are therefore not to be considered limiting of its scope, for the invention may admit to other equally effective embodiments.

FIG. 1 depicts a process chamber having an apparatus for generating and delivering a process gas suitable for processing a substrate in accordance with some embodiments of the present invention.

FIG. 2 depicts a schematic side view of a portion of an apparatus for generating and delivering a process gas in accordance with some embodiments of the present invention.

FIG. 3 depicts a schematic side view of a portion of an apparatus for generating and delivering a process gas in accordance with some embodiments of the present invention.

FIG. 4 depicts a schematic top view of a portion of an apparatus for generating and delivering a process gas in accordance with some embodiments of the present invention.

FIGS. 5-7 respectively depict schematic side views of a portion of an apparatus for generating and delivering a process gas in accordance with some embodiments of the present invention.

FIGS. 8A-B respectively depict schematic side and top views of a gas dispersion plate suitable for use with an apparatus for processing a substrate in accordance with some embodiments of the present invention.

FIGS. 9A-B respectively depict schematic side and top views of a gas dispersion plate suitable for use with an apparatus for processing a substrate in accordance with some embodiments of the present invention.

FIGS. 10A-B respectively depict schematic side and top views of a gas dispersion plate suitable for use with an apparatus for processing a substrate in accordance with some embodiments of the present invention.

To facilitate understanding, identical reference numerals have been used, where possible, to designate identical elements that are common to the figures. The figures are not drawn to scale and may be simplified for clarity. It is contemplated that elements and features of one embodiment may be beneficially incorporated in other embodiments without further recitation.

### DETAILED DESCRIPTION

Methods and apparatus for generating and delivering process gases for processing substrates are provided herein. In some embodiments, the inventive apparatus may advantageously provide source materials (e.g. solid state precursors) necessary to perform desired deposition processes while reducing or eliminating exposure of the operator to the toxic materials, thus increasing the safety and efficiency of the process. Embodiments of the inventive apparatus may further advantageously provide an automatic feed of the source materials, thereby reducing system downtime by providing the solid state precursor in substantially constant amounts and by reducing exposure of the solid state precursor to contaminants, thus maintaining a high purity of the solid state precursor. Although not limiting in scope, the apparatus may be particularly advantageous in applications such as epitaxial deposition of Group III-V semiconductor materials, for example, arsenic (As) containing materials.

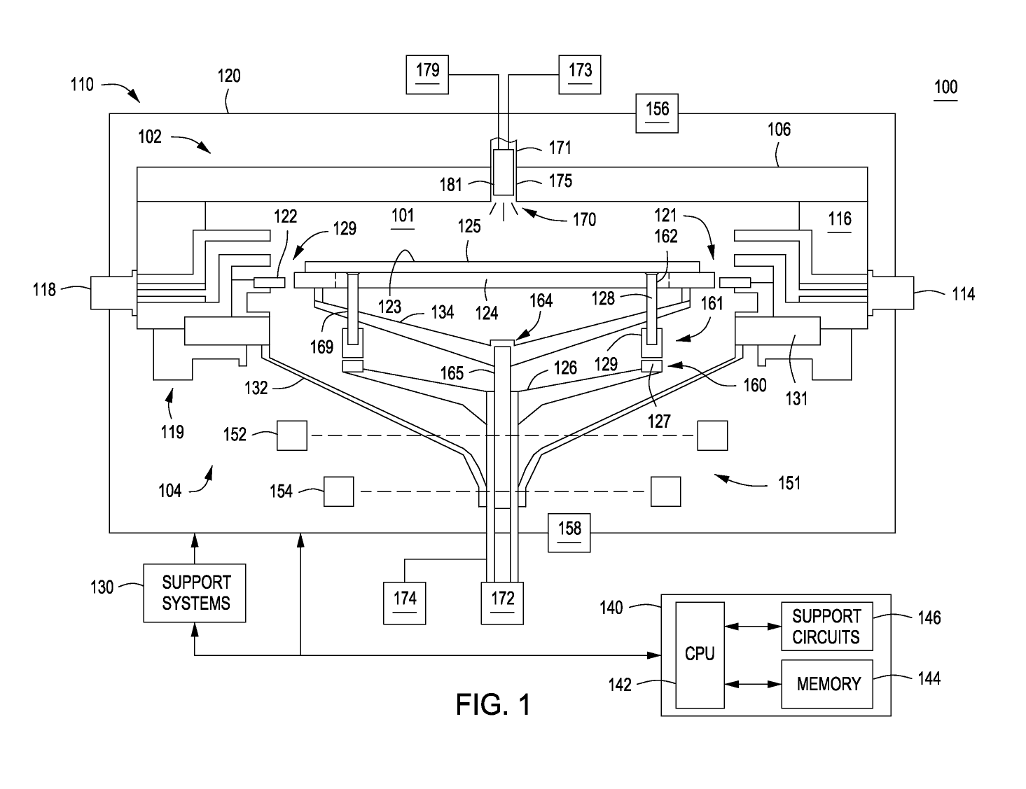

FIG. 1 depicts a schematic side view of a process chamber 100 in accordance with some embodiments of the present invention. In some embodiments, the process chamber 100 may be modified from a commercially available process chamber, such as the RP EPIC® reactor, available from Applied Materials, Inc. of Santa Clara, Calif., or any other suitable semiconductor process chamber adapted for performing deposition processes. It is contemplated the embodiments of the present invention may also be used with process chambers available from other manufacturers, and well as in connection with process chambers configured for other types of processes where sublimation or evaporation of a source material to provide a process gas is desired.

The process chamber 100 generally comprises a chamber body 110, a temperature-controlled reaction volume 101, one or more gas distribution mechanisms (top gas injector 170 and a side gas injector 114 shown) and a heated exhaust manifold 118. The process chamber 100 may further include support systems 130, and a controller 140, as discussed in more detail below.

The chamber body 110 generally includes an upper portion 102, a lower portion 104, and an enclosure 120. The upper portion 102 is disposed on the lower portion 104 and includes a chamber lid 106 and an upper chamber liner 116. In some embodiments, an upper pyrometer 156 may be provided to provide data regarding the temperature of the processing surface of the substrate during processing. Additional elements, such as a clamp ring disposed atop the chamber lid 106 and/or a baseplate on which the upper chamber liner may rest, have been omitted from the figure, but may optionally be included in the process chamber 100.

The chamber lid 106 may have any suitable geometry, such as flat (as illustrated) or having a dome-like shape. Other shapes, such as reverse curve lids are also contemplated. In some embodiments, the chamber lid 106 may comprise a energy reflective material, such as quartz or the like. Accordingly, the chamber lid 106 may at least partially reflect energy radiated from the substrate 125 and/or from lamps disposed below a substrate support 124 for supporting the substrate 125. The upper chamber liner 116 may be disposed above the injector 114 and heated exhaust manifold 118 and below the chamber lid 106, as depicted. In some embodiments the upper chamber liner 116 may comprise an energy reflective material, such as quartz or the like, for example, to at least partially reflect energy as discussed above. In some embodiments, the upper chamber liner 116, the chamber lid 106, and a lower chamber liner 131 (discussed below) are fabricated from quartz, thereby advantageously providing a quartz envelope surrounding the substrate 125.

The lower portion 104 generally comprises a baseplate assembly 119, a lower chamber liner 131, a lower dome 132, the substrate support 124, a pre-heat ring 122, a substrate lift assembly 160, a substrate support assembly 164, a heating system 151, and a lower pyrometer 158. The heating system 151 may be disposed below the substrate support 124 to provide heat energy to the substrate support 124. In some embodiments, the heating system 151 may comprise one or more outer lamps 152 and one or more inner lamps 154. Although the term “ring” is used to describe certain components of the process chamber, such as the pre-heat ring 122, it is contemplated that the shape of these components need not be circular and may include any shape, including but not limited to, rectangles, polygons, ovals, and the like. The lower chamber liner 131 may be disposed below the injector 114 and the heated exhaust manifold 118, for example, and above the baseplate assembly 119. The injector 114 and the heated exhaust manifold 118 are generally disposed between the upper portion 102 and the lower portion 104 and may be coupled to either or both of the upper portion 102 and the lower portion 104.

The one or more gas distribution mechanisms (top gas injector 170 and the side gas injector 114 shown) may be disposed about the process chamber 100 in any manner suitable to provide one or more process gases to a desired area of the reaction volume 101 to facilitate performing a desired process on the substrate 125. For example, in some embodiments, the side gas injector 114 may be disposed on a first side 121 of the substrate support 124 disposed inside the chamber body 110 to provide one or more process gases, across a processing surface 123 of a substrate 125 when the substrate is disposed in the substrate support 124. Alternatively, or in combination, in some embodiments, the top gas injector 114 may be disposed above the substrate 125 to provide one or more process gases directly to the processing surface 123 of a substrate 125.

Each of the one or more gas distribution mechanisms may provide the same, or in some embodiments, a different process gas to the reaction volume 101. The inventors have observed that providing the process gases via separate injectors allows the process gases to reach the desired area of the reaction volume 101 (e.g., proximate the processing surface 123 of the substrate 125) without reacting with one another. For example, in embodiments where an epitaxial deposition process is performed to deposit a Group III-V semiconductor material, the top gas injector 170 may provide a first process gas comprising a Group V element (e.g., arsenic (As), phosphorous (P), or the like). In such embodiments, the side gas injector 114 may provide a second process gas comprising a Group III element (e.g., boron (B), aluminum (Al), gallium (Ga), or the like) or a Group III metal-organic precursor (e.g., triethyl or trimethyl species, such as Trimethylgallium (Me₃Ga, TMGa), Trimethylaluminum (Me₃Al, TMA) and Trimethylindium (Me₃In, TMIn), or the like. In some embodiments, the first process gas and/or second process gas may optionally comprise at least one of a carrier gas (e.g. a hydrogen containing gas, a nitrogen containing gas, or the like) or a halide gas (e.g., chlorine gas (Cl2) or hydrogen chloride (HCl), or the like).

The inventors have observed that conventional Group III-V deposition processes typically use hydride sources such as arsine (AsH₃) and phosphine (PH₃) and organo-metallic compounds such as tertiarybutylarsine (TBA) and tertiarybutylphosphine (TBP). However, arsine (AsH₃) and phosphine (PH₃) are difficult to handle safely due to the high flammability and high toxicity of both compounds. In addition, the use of tertiarybutylarsine (TBA) and tertiarybutylphosphine (TBP) in such processes require complex and expensive delivery systems.

Accordingly, in some embodiments, the process chamber 100 may comprise an apparatus 181 configured to provide a gaseous precursor from a solid state precursor. By utilizing the apparatus 181, the inventors have observed that gaseous precursors (e.g., elemental, hydride based, chloride based, or the like) for the above discussed deposition processes may advantageously be produced in situ, thereby reducing or eliminating exposure of the operator to the toxic materials and increasing the safety and efficiency of the processes. In addition, in embodiments where an arsenic (As) solid state precursor is utilized, the low vapor pressure of arsenic (As) may advantageously provide an immediate stoppage of arsenic (As) flow at the conclusion of the process, thereby limiting exposure of the operator to arsenic (As) containing gases and further enhancing the safe operation of the process chamber 100.

In some embodiments, for example as shown in FIG. 1, the apparatus 181 may be integrated with the top gas injector 170. In such embodiments, the apparatus 181 may be disposed within a conduit 171 disposed within a through hole 175 of the chamber lid 106. In some embodiments, one or more mechanisms to provide process resources, for example, such as a gas supply 179 and a solid state precursor source 173 may be coupled to the apparatus 181. When present, the solid state precursor source 173 may advantageously feed material to the apparatus 181 continuously as needed, thereby decreasing downtime that would otherwise be necessary to manually provide the necessary materials for the process.

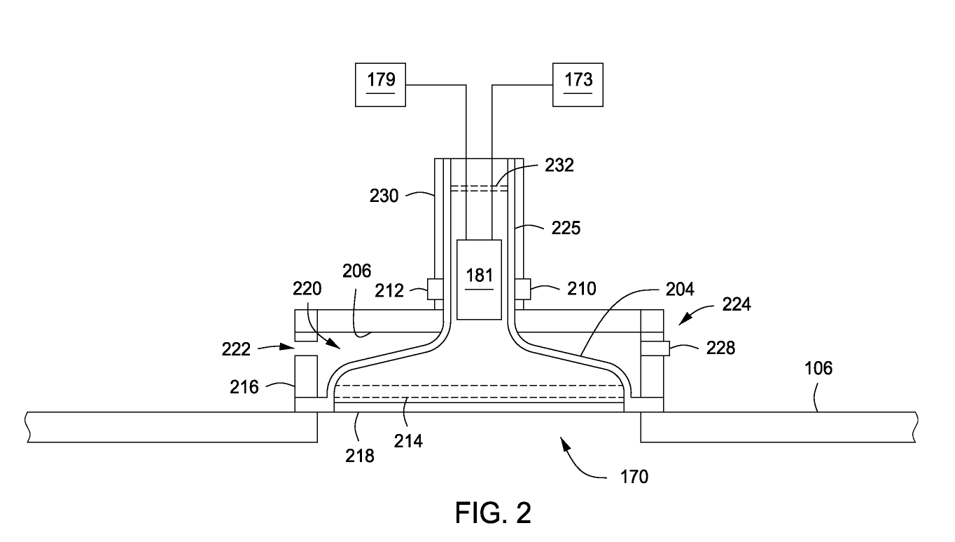

Referring to FIG. 2, in some embodiments, the top gas injector 170 may comprise a reactor 204. In some embodiments the reactor 204 may be dome-shaped, although other geometries may also be utilized. In such embodiments, the apparatus 181 may be disposed in an upper neck 225 of the reactor 204. In some embodiments, a disk 232 may be disposed within the upper neck 225 above the apparatus 181 to facilitate control over the temperature within the upper neck 225. The disk 232 may be fabricated from, for example, quartz (SiO₂), such as opaque quartz. The thickness of the disk 232 may be controlled and/or the addition of an inert reflective material may be added to facilitate controlling the temperature within the upper neck 225.

Alternatively, or in combination, a sleeve 230 fabricated from, for example silicon carbide (SiC) may be disposed about the upper neck 225 to provide control over a temperature within the upper neck 225 to prevent condensation. For example, if heat losses are too high, the sleeve 230 may comprise a thermally insulative material in order to retain more heat. Alternatively, if the temperature is too high, the sleeve may comprise cooling fins or the like to facilitate the removal of heat. The disk 232 and/or the sleeve 230 may be included to minimize heat losses to the outside and to prevent condensation of precursors that may back diffuse. Advantageously, no active control over the temperature is required.

In some embodiments, a housing 216 may be disposed about the reactor 204 to provide structural support and maintain the process environment within the process chamber. The housing 216 may comprise a flat or dome shape. In such embodiments, the housing 216 may comprise one or more reflecting surfaces (one reflecting surface 206 shown) to facilitate rapid and/or uniform heating of the reactor 204. In some embodiments, the housing 216 may comprise one or more first ports (one first port 222 shown) to allow a flow of air proximate an upper portion 220 of the reactor 204 that, in some embodiments, may be utilized to cool the upper portion 220. By air cooling the upper portion 220 of the reactor 204, the inventors have observed that unwanted deposition on the surfaces of the reactor 204 may be reduced or eliminated. Alternatively, or in combination, in some embodiments, the housing 216 may comprise one or more second ports (one second port shown 224) configured to accommodate a heating lamp 228. When present, the heating lamp 228 may facilitate control over the temperature of the reactor 204.

In some embodiments, a baffle (shown in phantom at 214) may be disposed within the reactor 204 to further facilitate control over the concentration distribution of the precursor. The reactor 204 may be fabricated from materials suitable to allow heating of the apparatus 181 and monitoring of parameters within apparatus 181 via one or more monitors (e.g., detector module 212) disposed proximate a portion of the reactor 204. In some embodiments, the apparatus 181 may be heated via radiant heat from a heat source (e.g., heating module 210), although other forms of heating may be utilized. In some embodiments, the reactor 204 may be fabricated from quartz. In some embodiments, the reactor 204 may include a distribution plate 218 (described below) configured to provide the precursor to a desired area within the process chamber.

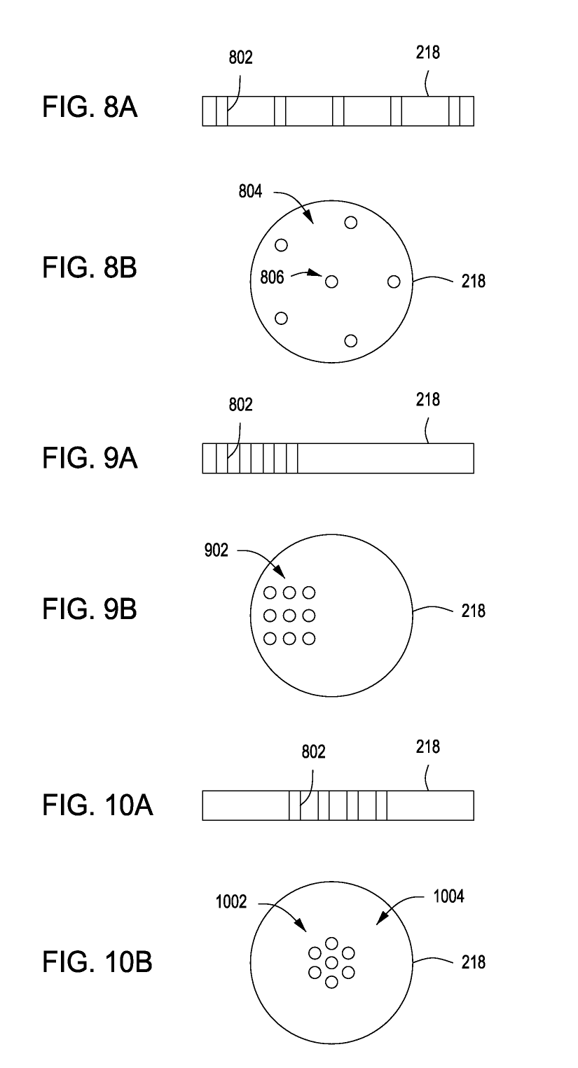

The gas distribution plate 218 may be configured to provide a concentration of the gaseous precursor to a desired area of a process chamber or substrate being processed in the process chamber. For example, in some embodiments, the gas distribution plate 218 may comprise a plurality of gas distribution holes 802 disposed proximate a peripheral edge 804 of the gas distribution plate 218, such as shown in FIGS. 8A-B. In such embodiments, one or more gas distribution holes 802 may be disposed proximate a center 806 of the gas distribution plate 218. In another example, in some embodiments, the gas distribution plate 218 may be configured asymmetrically, having the gas distribution holes 802 disposed proximate a first side 902 of the gas distribution plate 218, such as shown in FIGS. 9A-B. In another example, in some embodiments the gas distribution plate may be configured such that the gas distribution holes 802 are concentrated proximate a center 1002 of the gas distribution plate 218 with no gas distribution holes disposed proximate a peripheral edge 1004 of the gas distribution plate 218, such as shown in FIGS. 10A-B.

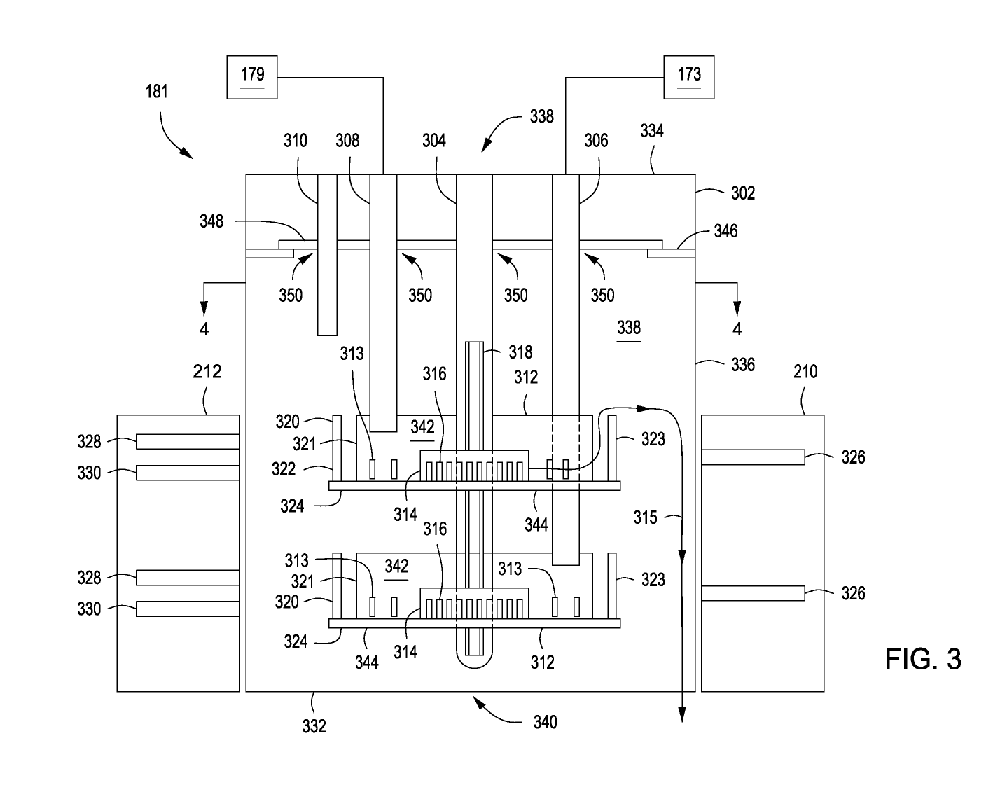

Referring to FIG. 3, the apparatus 181 may generally comprise a container 302, one or more solid precursor collection trays (two solid precursor collection trays 312 shown), one or more material delivery tubes (two material delivery tubes 308, 306 shown) to provide the solid state precursor to the one or more solid precursor collection trays 312, and a gas delivery tube 304 to provide a gas to the one or more solid precursor collection trays 312.

The container 302 generally comprises a lid 334, bottom 332 and sidewall 336, wherein the lid 334, bottom 332 and sidewall 336 define an inner volume 338. The container 302 may be fabricated from any suitable material that is non reactive with the solid state or gaseous precursor disposed therein while allowing heating of the inner volume 338 via radiant heat from a heat source (e.g., heating module 210) and the monitoring of parameters within apparatus 181 via one or more monitors (e.g., detector module 212) disposed proximate a portion of the reactor 204. In some embodiments, the container 302 may be fabricated from quartz (SiO₂).

In some embodiments, the lid 334 may comprise a plurality of through holes 338 configured to allow one or more conduits or tubes (e.g., gas delivery tube 304, a purge flow tube 310, material delivery tubes 306, 308, or the like) to pass through the lid 334. In some embodiments, the container 302 may comprise an inwardly facing flange 346 configured to support a baffle 348. The baffle 348 comprises a plurality of through holes 350 configured to allow the one or more tubes to pass through the baffle 348. When present, the inwardly facing flange 346 and/or baffle 348 support the one or more tubes, maintaining the one or more tubes in a desired position. The baffle 348, inwardly facing flange 346 and one or more tubes (gas delivery tube 304, a purge flow tube 310, material delivery tubes 306, 308) may be fabricated from any material that is non-reactive with the precursor and/or process gases provided to the container 302, for example, such as quartz (SiO₂).

In some embodiments, the bottom 332 of the container 302 may comprise a plurality of through holes 340 configured to allow the passage of gaseous precursor from the inner volume 338 of the container 302 to an inner volume of a process chamber (e.g., reaction volume 101 of process chamber 100 described above).

The one or more solid precursor collection trays 312 are disposed within the inner volume 338 of the container 302 and generally comprise an inner baffle 314 having a plurality of slots 316, an outer wall 321 comprising a plurality of slots 313 and a floor 344 coupling the inner baffle 314 to the outer wall 321. The floor 344, inner baffle 314 and outer wall 321 form a storage area 342 to hold the precursor.

In some embodiments, the solid state material may be provided to the one or more solid precursor collection trays 312 via one or more material delivery conduits (two material delivery conduits 306, 308 shown). The precursor may be any solid state material suitable to form a gaseous precursor to perform a desired process. For example, in embodiments where a Group III-V semiconductor material deposition process is performed on a substrate disposed in a process chamber (e.g., substrate 125 disposed in process chamber 100 described above), the solid state material may comprise an arsenic (As) precursor, such as arsenic pellets, granules, or powder, or the like.

In some embodiments, one or more radiant heaters (one radiant heater 320 per solid precursor collection tray 312 shown) are disposed proximate the outer wall 321 circumscribing the one or more solid precursor collection trays 312. In some embodiments, the one or more solid precursor collection trays 312 may include a flange 324 to support the one or more radiant heaters 320 (or the floor 344 may extend radially beyond the storage area 342. The one or more radiant heaters 320 may be fabricated from any material suitable to transfer heat from a heat source (e.g., heating lamps 326 of the heater module 210) to the one or more solid precursor collection trays 312. For example, in some embodiments, the one or more radiant 320 heaters may be fabricated from silicon carbide (SiC). In some embodiments, the temperature of the one or more radiant heaters 320 may be monitored by a temperature monitoring device, or sensor, (e.g., a pyrometer 328) disposed in the detector module 212.

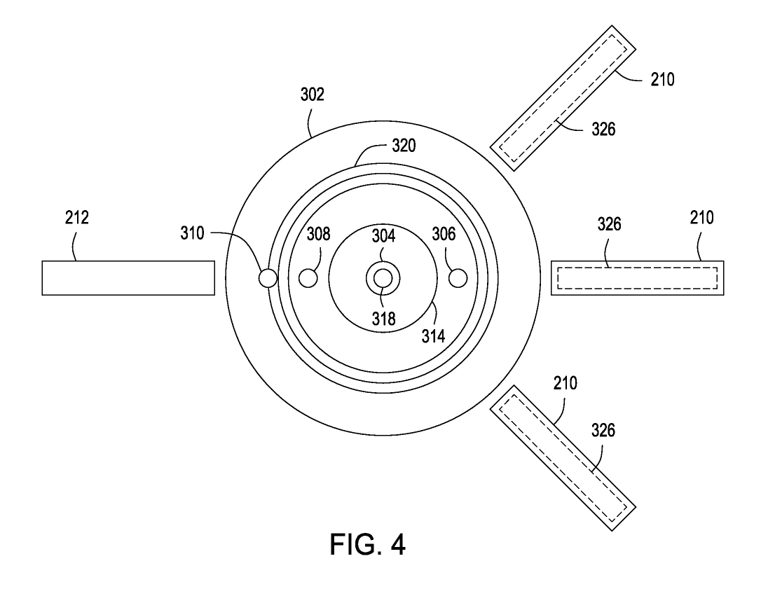

The heating lamps 326 may be any type of heating lamp suitable to heat the one or more radiant heaters 320 to a desired temperature. For example, in some embodiments, the heating lamps 326 may be similar to lamps utilized in a rapid thermal process chamber (RTP) or an epitaxial (EPI) chamber. In such embodiments, the lamps may have a capacity of up to about 650 W (e.g. such as RTP process chamber lamps), or in some embodiments up to about 2 kW (e.g., such as EPI process chamber lamps). Any number of heating lamps 326 may be utilized in any configuration suitable to provide adequate and efficient heating of the one or more radiant heaters 320. For example, in some embodiments, three heating modules 210 having one heating lamp 326 per solid precursor collection tray 312 may be disposed about the container 302, each heating module 210 separated from an adjacent heating module by about 60 degrees, such as shown in FIG. 4. Alternatively or in combination, other heating mechanisms may be utilized such as resistive heaters or heat exchangers.

Referring back to FIG. 3, in some embodiments, one or more of the one or more radiant heaters 320 may include a window 322 to allow a line of sight to the one or more solid precursor collection trays 312 from the detector module 212 to allow a temperature monitoring device (e.g., a pyrometer 330) of the detector module 212 to detect the temperature of the one or more solid precursor collection trays. In some embodiments, by monitoring the temperature of the one or more solid precursor collection trays 312, the amount of material within the one or more solid precursor collection trays 312 may also be monitored. For example, by monitoring changes in light emissivity of the precursor detected by the pyrometer 330, an amount of the precursor within the one or more solid precursor collection trays 312 may be ascertained. Thus, the detector module 212 may function as a precursor level sensor.

The gas delivery tube 304 provides one or more gases to the one or more solid precursor collection trays 312. The one or more gases may be any gases suitable to perform a desired process, for example such as a purge gas or carrier gas (e.g., a hydrogen gas, nitrogen gas, or the like) or an etch gas (e.g., a halide containing gas, such as hydrogen chloride (HCl), chlorine (Cl₂), hydrogen bromide (HBr), hydrogen iodide (HI), or the like). In some embodiments, the gas delivery tube 304 may comprise a heating element 318 disposed therein. The heating element 318 may be any type of heating element, for example such as a silicon carbide (SiC) radiant heating element to radiate heat absorbed from a lamp heater (e.g., heating module 210). When present, the heating element 318 provides control of the temperature of the gases provided by the gas delivery tube 304. By controlling the temperature of the gases provided by the gas delivery tube 304, the inventors have observed that a reaction between the gases provided by the gas delivery tube 304 and the precursor in the one or more solid precursor collection trays 312 may be controlled, thereby providing control over a concentration of the resultant process gas to the process chamber. For example, in embodiments where a hydrogen chloride gas and carrier gas is provided to an arsenic containing one or more solid precursor collection trays 312 a concentration of the resultant arsenic and halide gas (AsHₓCl_{y}) gas may be controlled by controlling the temperature of the hydrogen chloride gas and carrier gas via the heating element.

The purge flow tube 310 provides a purge gas to the facilitate purging of the container 302. In some embodiments, the purge flow tube 310 may be positioned to provide a purge gas (e.g. a hydrogen (H₂) gas, nitrogen (N₂) gas, or the like) proximate the window 322 to maintain a line of sight, thereby allowing the pyrometer 330 to take continuous accurate measurements.

In operation of the apparatus 181 as described in the above embodiments, the solid state precursor is provided to the storage area 342 of the one or more of the solid precursor collection trays 312 disposed in the container 302 via the material delivery tubes 306, 308. The solid state precursor may be provided manually to the material delivery tubes 306, 308, or in some embodiments via a solid state precursor dispenser, as described below. Next, the heating module 210 provides heat to the one or more radiant heaters 320 thus causing the one or more radiant heaters 320 to heat the solid precursor collection trays 312. As the solid precursor collection trays 312 are heated, the solid state precursor is evaporated or sublimed, thus forming a gaseous state. Next, a gas, for example, a carrier gas is provided to the solid precursor collection trays 312 via the gas delivery tube 304. In some embodiments, the gas provided by the gas delivery tube 304 may be heated to a desired temperature via the heating element 318. The carrier gas flows through the slots 316 of the inner baffle 314 to the storage area 342, combines with the gaseous precursor and carries the gaseous precursor through the slots 313 of the outer wall 321 of the precursor tray 312 and out of the bottom 332 of the container 302 and into the process chamber 100 (as indicated by arrow 315). During operation of the apparatus 181, the amount of solid state precursor material disposed in the solid precursor collection trays 312 may be monitored via the pyrometer 330 of the detector module 212 through the window 322 of the radiant heaters 320, 323. In some embodiments, when the amount of solid state precursor material falls below a predetermined amount, a dispenser (e.g. dispenser 500 described below) may automatically provide additional solid state precursor material.

The inventors have observed that conventional systems used to form gaseous precursors from solid state materials typically utilize pre-filled sealed ampoules to contain the solid state materials during the evaporation/sublimation process. However, when the solid state material contained within the pre-filled ampoules become exhausted the pre-filled ampoule must be removed from the process chamber and replaced, thus leading to process downtime. Moreover, the inventors have discovered that when using pre-filled ampoules the solid state material may pack unevenly during transportation or installation, thus leading to non-uniform gas movement or gas channeling through the solid state material, thereby causing to a non-uniform formation and/or dispersion of gaseous precursor.

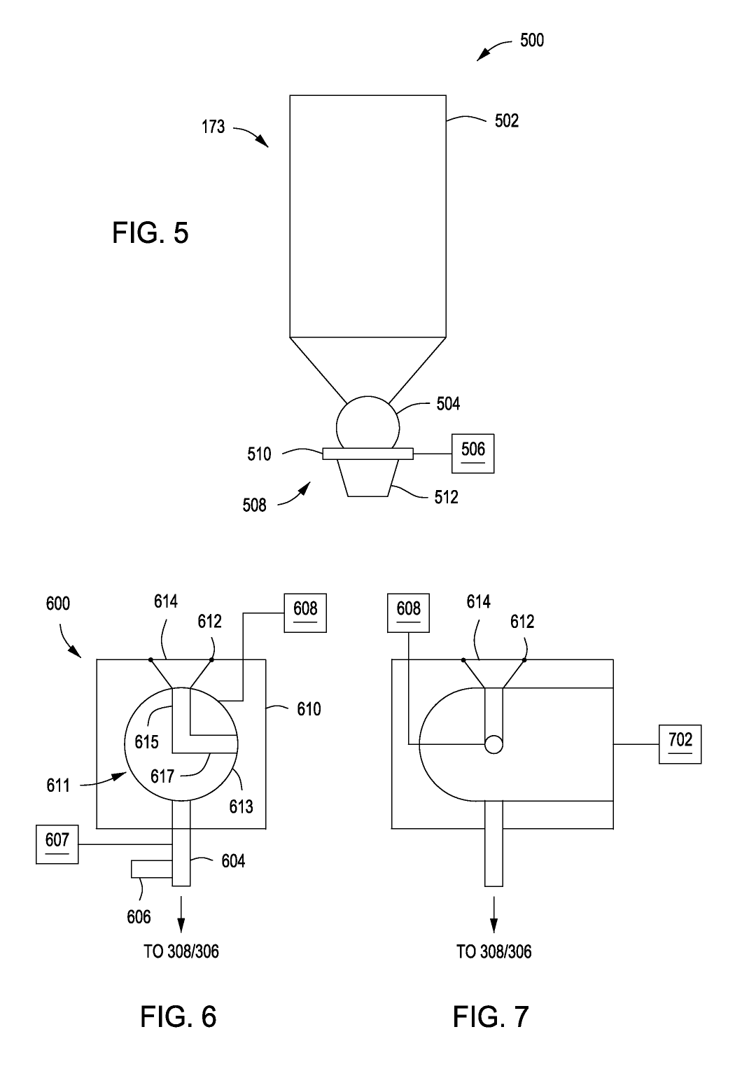

Accordingly, in some embodiments, the solid state precursor source 173 source may comprise a precursor dispenser 500 configured to provide the solid state precursor to the apparatus 181 (described above), for example as shown in FIG. 5. The precursor dispenser 500 generally comprises a hopper 502 to hold the solid state precursor, a valve 504 to control the flow of the solid state precursor and a fill port 508 to dispense the solid state precursor.

In some embodiments, the hopper 502 may be filled with the solid state precursor in a hermetically sealed box (e.g., a glove box) and then sealed under vacuum prior to use, thus eliminating any direct contact an operator has with the solid state precursor. The hopper 502 may be fabricated from any non-reactive material suitable to hold the solid state precursor and maintain structural integrity under vacuum. For example, in some embodiments the hopper 502 may be fabricated from quartz (SiO₂).

The valve 504 may be any type of valve suitable to uniformly disperse the solid state precursor, for example such as a plug valve or ball valve. The fill port 508 may generally comprise a tapered end 512 and a flange 510. In some embodiments, the tapered end 512 is configured to interface with the material delivery tubes 306, 308 (described above) or an automatic dispensing mechanism (e.g., dispensing mechanism 600 described below) and the flange 510 is configured to interface with an opposing surface to facilitate a vacuum seal between the precursor dispenser and the surface (e.g., a surface of the dispensing mechanism 600 described below). In some embodiments, a gas supply 506 may be coupled to the fill port 508 to provide a purge gas to the fill port 508. Providing a purge gas (e.g., an inert gas such as argon (Ar), helium (He), or the like) may facilitate continuous flow of the solid state precursor through the fill port 512. The valve 504 and fill port 508 may be fabricated from any material that is non-reactive with the solid state precursor, for example such as stainless steel or quartz (SiO₂).

In some embodiments, the precursor dispenser 500 may further comprise a dispensing mechanism 600, for example such as shown in FIG. 6. When present, the dispensing mechanism 600 may provide the solid state precursor to the apparatus 181 (described above) automatically. By providing the solid state precursor automatically, the inventors have discovered that possible exposure of the operator to the solid state precursor may be reduced or eliminated, thus making the process safer and more efficient. In addition, providing the solid state precursor automatically may reduce system downtime by providing the solid state precursor in substantially constant amounts and by reducing exposure of the solid state precursor to contaminants, thus maintaining a high purity of the solid state precursor.

The dispensing mechanism 600 may be any type of material dispenser suitable to provide the solid state precursor when needed. For example, in some embodiments, the dispensing mechanism 600 may be a rotatable precursor dispenser, such as shown in FIG. 6. In such embodiments, the dispensing mechanism 600 may comprise a body 610 containing a substantially circular hollow inner volume 611, an inlet port 614, a plug 613 disposed within the inner volume 611, and an outlet port 604.

The body 610 may be fabricated from any material that is non-reactive to the solid state precursor, for example such as stainless steel. The inlet port 614 is coupled to the inner volume 611 and, in some embodiments, may be configured to interface with a fill port (e.g., fill port 512 described above). In some embodiments, an o-ring 612 may be disposed about the inlet port 614 to facilitate a vacuum seal with an opposing surface, for example, such as the flange 510 of the fill port 512 described above.

The plug 613 may be fabricated from any material that is non-reactive to the solid state precursor and has a low coefficient of friction to allow the plug to rotate within the inner volume 611 freely. For example, in some embodiments, the plug 613 may be fabricated from a polymer such as polytetrafluoroethylene (PTFE). The plug 613 comprises a first hole 615 and a second hole 617 formed therein, wherein the first hole 615 and second hole 617 are fluidly coupled to one another. In some embodiments, a gas supply 608 is coupled to the inner volume 611 to provide pulses of inert gas to the first hole 615 and second hole 617 to facilitate flow of the solid state precursor and prevent packing of the solid state precursor within the first hole 615 and second hole 617.

In some embodiments, a sensor 606, for example an optical sensor or pressure sensor may be coupled to the outlet to facilitate monitoring a pressure within the outlet 604 or the flow of solid state precursor through the outlet 604. In some embodiments, a gas supply 607 may be coupled to the outlet port 604 to provide pulses of inert gas to facilitate a flow of the solid state precursor through the outlet port 604.

In some embodiments, a motor 702, for example, such as a stepper motor, may be coupled to the plug 613 to control rotation thereof, such as shown in FIG. 7. In operation of the dispensing mechanism 600 as described in FIGS. 6 and 7, the solid state precursor is provided to the inlet 614 from, for example, the precursor dispenser 500. The solid state precursor flows into the first hole 615 of the plug 613. The plug 613 is then rotated via the motor 702 until the second hole 617 is aligned with the outlet port 604. The gas supply 608 provides one or more pulses of gas, forcing the solid state precursor to flow from the second hole 617 to the outlet port 604, thereby dispensing the solid state precursor.

Returning to FIG. 1 to describe the remainder of the exemplary process chamber 100, the substrate support 124 may be any suitable substrate support, such as a plate (as illustrated in FIG. 1) or a ring (as illustrated by dotted lines in FIG. 1) to support the substrate 125 thereon. The substrate support assembly 164 generally includes a support bracket having a plurality of support pins coupled to the substrate support 124. The substrate lift assembly 160 may be disposed about the central support 165 and axially moveable therealong. The substrate lift assembly 160 comprises a substrate lift shaft 126 and a plurality of lift pin modules 161 selectively resting on respective pads 127 of the substrate lift shaft 126. In some embodiments, a lift pin module 161 comprises an optional base 129 and a lift pin 128 coupled to the base 129. Alternatively, a bottom portion of the lift pin 128 may rest directly on the pads 127. In addition, other mechanisms for raising and lowering the lift pins 128 may be utilized.

Each lift pin 128 is movably disposed through the lift pin hole 169 in each support arm 134 and can rest on the lift pin supporting surface when the lift pin 128 is in a retracted position, for example, such as when the substrate 125 has been lowered onto the substrate support 124. In some embodiments, such as when the substrate support 124 comprises a plate or susceptor, an upper portion of the lift pin 128 is movably disposed through an opening 162 in the substrate support 124. In operation, the substrate lift shaft 126 is moved to engage the lift pins 128. When engaged, the lift pins 128 may raise the substrate 125 above the substrate support 124 or lower the substrate 125 onto the substrate support 124.

The substrate support 124 may further include a lift mechanism 172 and a rotation mechanism 174 coupled to the substrate support assembly 164. The lift mechanism 172 can be utilized to move the substrate support 124 in a direction perpendicular to the processing surface 123 of the substrate 125. For example, the lift mechanism 172 may be used to position the substrate support 124 relative to the top gas injector 170 and the side gas injector 114. The rotation mechanism 174 can be utilized for rotating the substrate support 124 about a central axis. In operation, the lift mechanism may facilitate dynamic control of the position of the substrate 125 with respect to the flow field created by top gas injector 170 and the side gas injector 114. Dynamic control of the substrate 125 position in combination with continuous rotation of the substrate 125 by the rotation mechanism 174 may be used to optimize exposure of the processing surface 123 of the substrate 125 to the flow field to optimize deposition uniformity and/or composition and minimize residue formation on the processing surface 123.

During processing, the substrate 125 is disposed on the substrate support 124. The lamps 152, and 154 are sources of infrared (IR) radiation (i.e., heat) and, in operation, generate a pre-determined temperature distribution across the substrate 125. The chamber lid 106, the upper chamber liner 116, and the lower dome 132 may be formed from quartz as discussed above; however, other IR-transparent and process compatible materials may also be used to form these components. The lamps 152, 154 may be part of a multi-zone lamp heating apparatus to provide thermal uniformity to the backside of the substrate support 124. For example, the heating system 151 may include a plurality of heating zones, where each heating zone includes a plurality of lamps. For example, the one or more lamps 152 may be a first heating zone and the one or more lamps 154 may be a second heating zone. Further, the lower dome 132 may be temperature controlled, for example, by active cooling, window design or the like, to further aid control of thermal uniformity on the backside of the substrate support 124, and/or on the processing surface 123 of the substrate 125.

The support systems 130 include components used to execute and monitor pre-determined processes (e.g., growing epitaxial silicon films) in the process chamber 100. Such components generally include various sub-systems. (e.g., gas panel(s), gas distribution conduits, vacuum and exhaust sub-systems, and the like) and devices (e.g., power supplies, process control instruments, and the like) of the process chamber 100.

The controller 140 may be coupled to the process chamber 100 and support systems 130, directly (as shown in FIG. 1) or, alternatively, via computers (or controllers) associated with the process chamber and/or the support systems. The controller 140 may be one of any form of general-purpose computer processor that can be used in an industrial setting for controlling various chambers and sub-processors. The memory, or computer-readable medium, 144 of the CPU 142 may be one or more of readily available memory such as random access memory (RAM), read only memory (ROM), floppy disk, hard disk, or any other form of digital storage, local or remote. The support circuits 146 are coupled to the CPU 142 for supporting the processor in a conventional manner. These circuits include cache, power supplies, clock circuits, input/output circuitry and subsystems, and the like.

Thus, methods and apparatus for generating and delivering process gases for processing substrates are provided herein. In some embodiments, the inventive apparatus may advantageously provide source materials (e.g. solid state precursors) necessary to perform desired deposition processes while reducing or eliminating exposure of the operator to the toxic materials, thus increasing the safety and efficiency of the process. The inventive apparatus may further advantageously provide an automatic feed of the source materials, thereby reducing system downtime by providing the solid state precursor in substantially constant amounts and by reducing exposure of the solid state precursor to contaminants, thus maintaining a high purity of the solid state precursor. Although not limiting in scope, the apparatus may be particularly advantageous in applications such as process chambers configured for epitaxial deposition of Group III-V semiconductor materials, for example, arsenic (As) containing materials.

While the foregoing is directed to embodiments of the present invention, other and further embodiments of the invention may be devised without departing from the basic scope thereof.

1. An apparatus for processing a substrate, comprising:
a container comprising a lid, a bottom, and a sidewall, wherein the lid, the bottom, and the sidewall define an open area;
a solid precursor collection tray disposed within the open area;
a gas delivery tube disposed within the open area and extending toward the solid precursor collection tray to provide a gas proximate the solid precursor collection tray; and
a purge flow conduit coupled to the open area.

2. The apparatus of claim 1, wherein the apparatus further comprises a precursor delivery tube disposed within the open area and extending toward the solid precursor collection tray.

3. The apparatus of claim 2, wherein the precursor delivery tube further comprises:
a first end coupled to an precursor dispenser; and
a second end disposed above a storage area of the solid precursor collection tray.

4. The apparatus of claim 3, wherein the precursor dispenser further comprises:
a removable hopper comprising a hopper container and least one of a plug valve or a ball valve coupled to a bottom of the hopper container;
a fill port, wherein the removable hopper is fitted to the fill port;
a rotatable precursor dispenser coupled to the fill port; and
a first gas supply coupled to the rotatable precursor dispenser.

5. The apparatus of claim 4, wherein the hopper container is made of quartz.

6. The apparatus of claim 4, wherein the rotatable precursor dispenser is coupled to the precursor delivery tube.

7. The apparatus of claim 4, wherein the first gas supply is a nitrogen gas supply.

8. The apparatus of claim 1, wherein the container is made of quartz.

9. The apparatus of claim 1, wherein the apparatus further comprises a gas dispersion plate coupled to the bottom of the container.

10. The apparatus of claim 9, wherein the gas dispersion plate further comprises a plurality of holes arranged in a desired pattern to disperse the gas flowing through the gas dispersion plate.

11. The apparatus of claim 1, wherein the solid precursor collection tray further comprises:
an outer wall;
a floor coupled to the outer wall, wherein the floor and the outer wall define a storage area of the solid precursor collection tray;
a radiant heater circumscribing the outer wall; and
a baffle disposed within the storage area.

12. The apparatus of claim 11, wherein the outer wall, floor, and baffle are made of quartz.

13. The apparatus of claim 11, wherein the outer wall further comprises a plurality of holes.

14. The apparatus of claim 11, wherein the radiant heater is made of silicon carbide.

15. The apparatus of claim 11, wherein the solid precursor collection tray further comprises:
a plurality of heating lamps circumscribing the radiant heater;
a plurality of windows disposed within the radiant heater; and
a plurality of sensors circumscribing the windows to detect at least one of a temperature of the radiant heater or a level of the precursor disposed on the precursor collection tray.

16. The apparatus of claim 15, wherein the plurality of sensors comprise a pyrometer and a precursor level sensor.

17. The apparatus of claim 11, wherein the baffle further comprises a plurality of slots to allow a gas from a second gas source to enter the storage area.

18. The apparatus of claim 17, wherein the gas delivery tube further comprises:
a first end coupled to the second gas source;
a second end disposed though a hole in a top of the baffle;
a plurality of holes within the second end to allow the gas from the second gas source to escape the gas delivery tube; and
a silicon carbide tube disposed within the gas delivery tube.

19. The apparatus of claim 18, wherein the second gas source provides a gas comprising at least one of hydrogen, nitrogen, hydrogen chloride, or chlorine.

20. The apparatus of claim 1, wherein the gas delivery tube is made of quartz.
